(19) United States
(12) Patent Application Publication
(10) Pub. No.: US 2026/0334343 A1
(43) Pub. Date: Oct. 22, 2026

(54) DIAMOND-BASED HYBRID BONDING FOR STACKED SEMICONDUCTOR SYSTEMS

(71) Applicant: Micron Technology, Inc., Boise, ID (US)

(72) Inventors: Chenxi Li, Boise, ID (US); Kyle K. Kirby, Eagle, ID (US)

(21) Appl. No.: 19/458,527

(22) Filed: Jan. 23, 2026

Related U.S. Application Data
(60) Provisional application No. 63/753,302, filed on Feb. 3, 2025.

(51) Int. Cl. H10W 90/00; H10B 80/00; H10D 80/30; H10W 40/00; H10W 40/20; H10W 72/90; H10W 80/00; H10W 42/00

(52) U.S. Cl. CPC H10W 90/792; H10B 80/00; H10D 80/30; H10W 40/03; H10W 40/233; H10W 72/9415; H10W 80/312; H10W 80/327; H10W 80/721; H10W 80/732; H10W 80/743; H10W 42/101

(57) ABSTRACT

Methods, systems, and devices for diamond-based hybrid bonding for stacked semiconductor systems are described. For example, a stacked semiconductor system may be configured to implement one or more portions of diamond-form carbon (e.g., sp3 carbon, in which carbon atoms are bonded with four other carbon atoms) along a bonding interface (e.g., a hybrid bonding interface) between semiconductor components. In some examples, diamond-form carbon may be formed as a surface layer on one or both semiconductor components to be bonded, and one or more conductive paths may be formed through the one or more layers of diamond-form carbon. The diamond-form carbon may have a relatively low electrical conductivity and a relatively high thermal conductivity, and may support relatively higher bonding strength and relatively lower conductor and moisture migration rates than other techniques.

### CROSS REFERENCE

The present Application for Patent claims priority to U.S. Patent Application No. 63/753,302 by Li et al., entitled “DIAMOND-BASED HYBRID BONDING FOR STACKED SEMICONDUCTOR SYSTEMS,” filed Feb. 3, 2025, which is assigned to the assignee hereof, and which is expressly incorporated by reference in its entirety herein.

### TECHNICAL FIELD

The following relates to one or more semiconductor systems, including diamond-based hybrid bonding for stacked semiconductor systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports diamond-based hybrid bonding for stacked semiconductor systems in accordance with examples as disclosed herein.

FIGS. 2 and 3 show examples of systems that support diamond-based hybrid bonding for stacked semiconductor systems in accordance with examples as disclosed herein.

FIGS. 4A-4F show examples of fabrication operations that support diamond-based hybrid bonding for stacked semiconductor systems in accordance with examples as disclosed herein.

FIG. 5 shows a flowchart illustrating a method or methods that support diamond-based hybrid bonding for stacked semiconductor systems in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some stacked semiconductor systems may implement a hybrid bonding technique that includes fusing respective conductor portions and fusing respective dielectric portions at surfaces of interfacing semiconductor components, which may support relatively small pitch for conductive paths (e.g., vias, contacts, interconnects) between the interfacing semiconductor components (e.g., a relatively high interconnection density). However, some dielectric materials implemented at or near a hybrid bonding interface, such as silicon-based dielectric materials (e.g., silicon oxide, silicon nitride, silicon carbon nitride, silicon oxygen carbide), may be associated with relatively weak bonding performance or relatively long durations for manufacturing, which may limit yield of such stacked components. Additionally, or alternatively, some such dielectric materials may be associated with relatively poor barrier characteristics that may allow migration of conductor material or moisture into other portions of a semiconductor component, which may be accompanied by one or more other dielectric layers implemented as a moisture barrier or a conductor barrier. In some examples, implementations of one or more dielectric layers may be associated with relatively poor thermal conductivity that suppresses heat rejection from the stacked components, leading to relatively high temperatures or hot spots in a stacked semiconductor system.

In accordance with examples as disclosed herein, a stacked semiconductor system may be configured to implement one or more portions of diamond-form carbon (e.g., sp3 carbon, in which carbon atoms are bonded with four other carbon atoms) along a bonding interface (e.g., a hybrid bonding interface) between semiconductor components. For example, diamond-form carbon may be formed as a surface layer on one or both semiconductor components to be bonded, and one or more conductive paths (e.g., interconnections) may be formed through the one or more layers of diamond-form carbon. The diamond-form carbon may have a relatively low electrical conductivity and a relatively high thermal conductivity, and may support relatively higher bonding strength and relatively lower conductor and moisture migration rates than other techniques, which may provide relatively improved performance in a relatively smaller package size (e.g., reduced thickness, reduced cross-sectional area).

In addition to applicability in memory systems as described herein, techniques for may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by supporting relatively greater heat rejection, mechanical strength, and circuitry density in stacked semiconductor architectures, which may increase system throughput, reduce latency, and improve fabrication yield rates, among other benefits.

Features of the disclosure are illustrated and described in the context of systems and architectures. Features of the disclosure are further illustrated and described in the context of manufacturing operations and flowcharts.

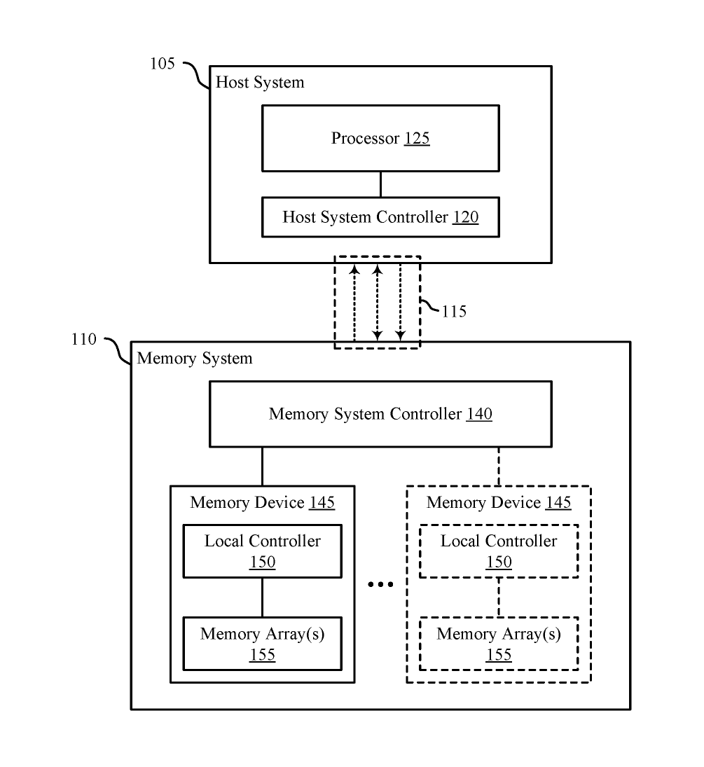

FIG. 1 shows an example of a system 100 that supports diamond-based hybrid bonding for stacked semiconductor systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks, or in one or more other dies. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with one or more logic dies (e.g., that include aspects of the host system 105, that are coupled with another set of one or more dies that includes the host system 105) that includes interface blocks operable to access a set of memory arrays 155 distributed across the one or more second dies.

Some examples of a system 100, or portion thereof, that includes a stacked semiconductor architecture may implement a hybrid bonding technique that includes fusing respective conductor portions and fusing respective dielectric portions at surfaces of interfacing semiconductor components, which may support relatively small pitch for conductive paths (e.g., vias, contacts, interconnects) between the interfacing semiconductor components (e.g., a relatively high interconnection density). However, some dielectric materials implemented at or near a hybrid bonding interface, such as silicon-based dielectric materials (e.g., silicon oxide, silicon nitride, silicon carbon nitride, silicon oxygen carbide), may be associated with relatively weak bonding performance or relatively long durations for manufacturing, which may limit yield of such stacked components. Additionally, or alternatively, some such dielectric materials may be associated with relatively poor barrier characteristics that may allow migration of conductor material or moisture into other portions of a semiconductor component, which may be accompanied by one or more other dielectric layers implemented as a moisture barrier or a conductor barrier. In some examples, implementations of one or more dielectric layers may be associated with relatively poor thermal conductivity that suppresses heat rejection from the stacked components, leading to relatively high temperatures or hot spots in a stacked semiconductor system.

In accordance with examples as disclosed herein, a system 100, or portion thereof, that includes a stacked semiconductor architecture may implement one or more portions of diamond-form carbon along a bonding interface between semiconductor components. For example, diamond-form carbon may be formed as a surface layer on one or both semiconductor components to be bonded, and one or more conductive paths may be formed through the one or more layers of diamond-form carbon. The diamond-form carbon may have a relatively low electrical conductivity and a relatively high thermal conductivity, and may support relatively higher bonding strength and relatively lower conductor and moisture migration rates than other techniques, which may provide relatively improved performance in a relatively smaller package size.

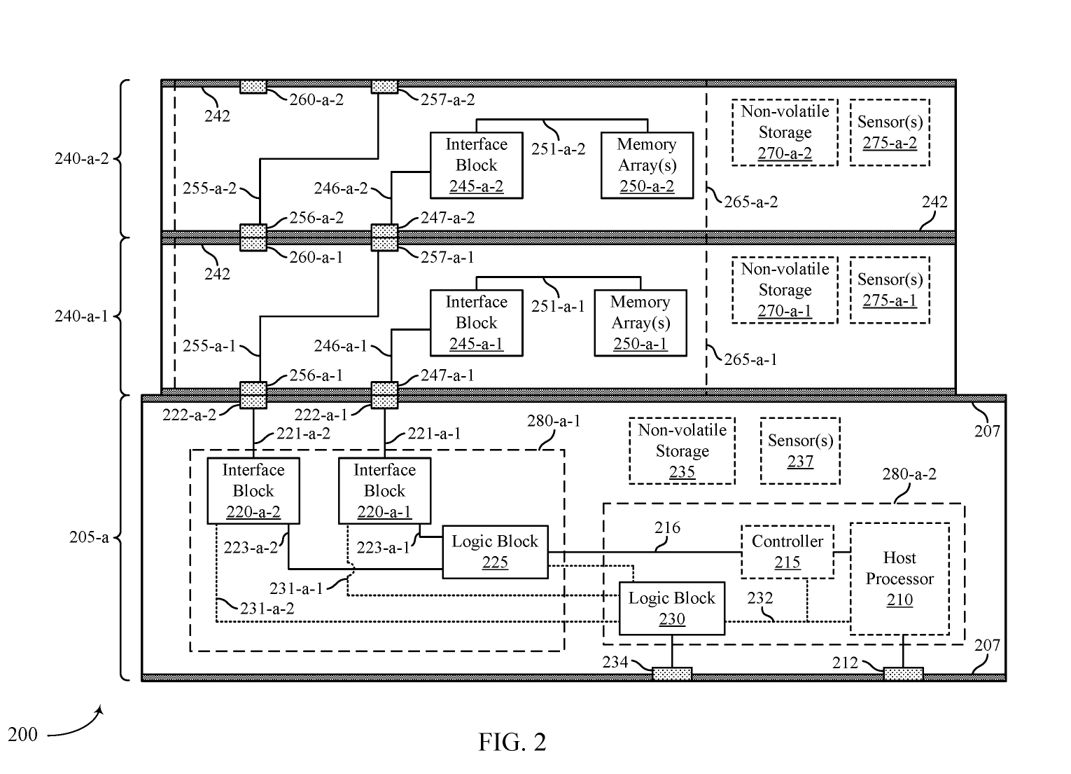

FIG. 2 shows an example of a system 200 (e.g., a semiconductor system, a system of coupled semiconductor dies, an HBM system, a 3D stacked memory system) that supports diamond-based hybrid bonding for stacked semiconductor systems in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations, a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In some examples, a dielectric material 207 or a dielectric material 242 may include a silicon-based dielectric material, or other dielectric material that may be associated with relatively weak bonding performance, relatively long durations for manufacturing, relatively poor barrier characteristics (e.g., that may allow migration of conductor material of contacts 222, contacts 247, contacts 256, contacts 257, or contacts 260 into circuitry of a die 205 or a die 240), or relatively poor thermal conductivity (e.g., that suppresses heat rejection from a die 205 or a die 240). In accordance with examples as disclosed herein, a system 200 may implement one or more portions of diamond-form carbon along a bonding interface between dies (e.g., included in a dielectric material 207, a dielectric material 242, or both). For example, diamond-form carbon may be formed as a surface layer on a die 205 or a die 240 and one or more conductive paths (e.g., including contacts 222, contacts 247, contacts 256, or contacts 257) may be formed through the one or more layers of diamond-form carbon. The diamond-form carbon may have a relatively low electrical conductivity and a relatively high thermal conductivity, and may support relatively higher bonding strength and relatively lower conductor and moisture migration rates than other techniques, which may provide relatively improved performance of a system 200 in a relatively smaller package size.

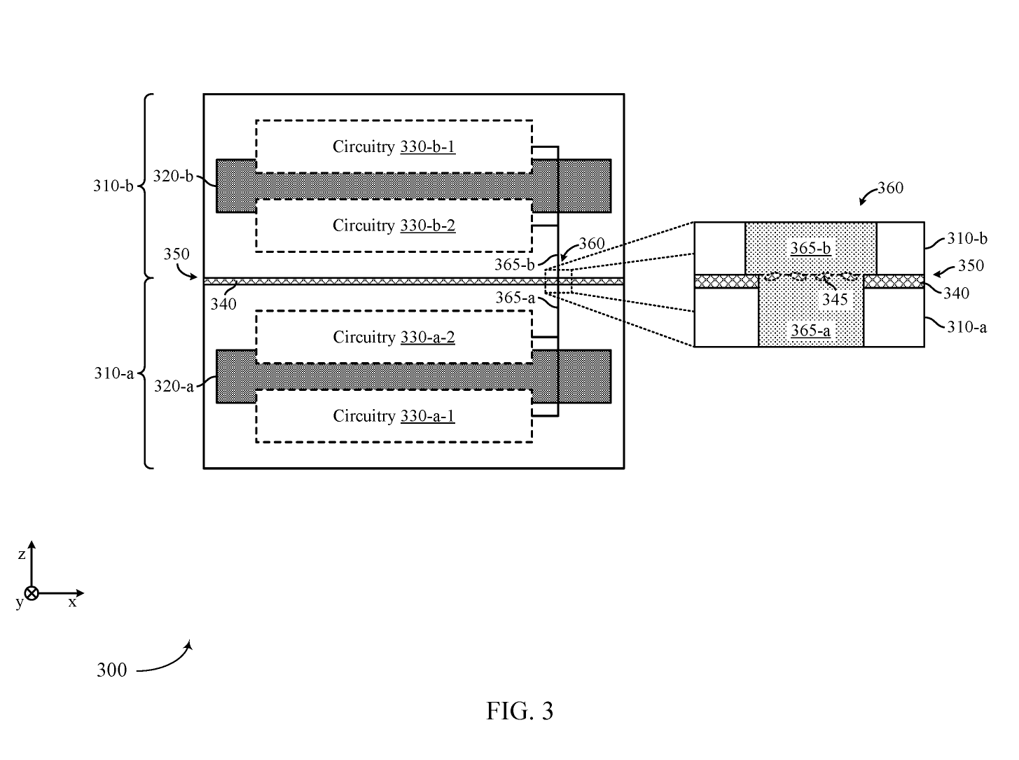

FIG. 3 shows an example of a system 300 (e.g., a semiconductor system) that supports diamond-based hybrid bonding for stacked semiconductor systems in accordance with examples as disclosed herein. The system 300 includes components 310 (e.g., components 310-a and 310-b, semiconductor components) that are bonded along an interface 350 (e.g., a bonding interface). Aspects of the system 300 may be described with reference to an x-direction, a y-direction, and a z-direction of the illustrated coordinate system, with FIG. 3 providing a view in an xz-plane. In some implementations, the z-direction may be a thickness direction of the components 310 or a stacking direction, and the interface 350 may be associated with respective surfaces (e.g., bonding surfaces) of the components 310 in xy-planes.

Each of the components 310 may be an example of respective type of semiconductor component. For example, each of the components 310 may be a semiconductor wafer (e.g., before singulation into dies), a stack of semiconductor wafers, a semiconductor die (e.g., after singulation from a wafer), a stack of semiconductor dies, or a reconstructed semiconductor wafer or die (e.g., including a set of multiple chiplets), among other examples. In some examples, the component 310-a may be set of one or more semiconductor wafers and the component 310-b may be semiconductor die (e.g., illustrative of a chip-to-wafer bonding arrangement) or a stack of semiconductor dies (e.g., illustrative of a stack-to-wafer bonding arrangement). In some other examples, the component 310-b may be set of one or more semiconductor wafers and the component 310-a may be semiconductor die or a stack of semiconductor dies. In some other examples, the component 310-a may be a set of one or more semiconductor dies and the component 310-b may be another set of one or more semiconductor dies (e.g., illustrative of a die-to-die, stack-to-die, or stack-to-stack bonding arrangement). In some other examples, the component 310-a may be a set of one or more semiconductor wafers and the component 310-b may be another set of one or more semiconductor wafers (e.g., illustrative of a wafer-to-wafer bonding arrangement, before singulation).

Each of the components 310 may include a respective substrate 320 (e.g., a semiconductor substrate, a crystalline semiconductor substrate, a crystalline silicon substrate, an SOI substrate, a SOG substrate, an SOS substrate, a glass substrate) and circuitry 330 . In some examples, circuitry 330 (e.g., transistor circuitry) may be formed at least in part from a doped portion of the respective substrate 320. For example, the component 310-a may include circuitry 330-a, and the component 310-b may include circuitry 330-b that is coupled with (e.g., electrically) the circuitry 330-a via any quantity of one or more conductive paths 360 through the interface 350.

Circuitry 330 may include memory circuitry (e.g., one or more memory arrays, memory controller circuitry for accessing one or more memory arrays), processor circuitry (e.g., one or more processing cores), or a combination thereof, among other types of circuitry. For example, a component 310 may be an example of one or more dies 240, in which case circuitry 330 may include interface block(s) 245, memory array(s) 250, or a combination thereof. In another example, a component 310 may be an example of one or more dies 205, in which case circuitry 330 may include interface block(s) 220, logic block(s) 225, logic block(s) 230, controller(s) 215, host processor(s) 210, or a combination thereof. In an HBM implementation, for example, one of the component 310-a or the component 310-b may include memory array circuitry (e.g., of one or more units 265) and the other of the component 310-a or the component 310-b may include memory controller circuitry (e.g., of one or more units 280-a-1) configured for accessing the memory array circuitry. In a 3D stacked memory implementation, for example, one of the component 310-a or the component 310-b may include memory array circuitry (e.g., of a memory system 110, of one or more units 265) and the other of the component 310-a or the component 310-b may include processing circuitry (e.g., of a host system 105, of one or more units 280-a-2) configured for performing operations (e.g., of an application) using data storage of the memory array circuitry. In a stacked NAND implementation, for example, one of the component 310-a or the component 310-b may include memory arrays (e.g., 3D NAND arrays) and the other of the component 310-a or the component 310-b may include circuitry (e.g., decoder circuitry, sensing circuitry, logic circuitry, complementary metal-oxide semiconductor (CMOS) circuitry) configured for accessing the memory arrays. In a hybrid memory implementation (e.g., in accordance with a heterogeneous integration), for example, circuitry 330-a may include memory array circuitry associated with a first storage architecture (e.g., a volatile architecture, a DRAM architecture, an SRAM architecture) and circuitry 330-b may include memory array circuitry associated with a second storage architecture (e.g., a non-volatile architecture, a NAND architecture, a chalcogenide architecture). Although each component 310 is illustrated with a single substrate 320, in some examples, a component may include multiple substrates 320 each with associated circuitry 330 (e.g., when a component 310 is a stack of dies or a stack of wafers).

In some examples, the component 310-a may include circuitry a-330-a-1, such that a doped portion of the substrate 320-a faces away from the interface 350 (e.g., along the negative z-direction, in accordance with a back-side bonding of the component 310-a). In some examples, the component 310-a may include circuitry 330-a-2, such that a doped portion of the substrate 320-a faces toward the interface 350 (e.g., along the positive z-direction, in accordance with a front-side bonding of the component 310-a). In some examples, the component 310-b may include circuitry 330-b-1, such that a doped portion of the substrate 320-b faces away from the interface 350 (e.g., along the positive z-direction, in accordance with a back-side bonding of the component 310-b). In some examples, the component 310-b may include circuitry 330-b-2, such that a doped portion of the substrate 320-b faces toward the interface 350 (e.g., along the negative z-direction, in accordance with a front-side bonding of the component 310-b). Thus, the described techniques may be implemented to support various back-to-back, front-to-back, and front-to-front bonding arrangements. For example, in front-to-back bonding arrangements, the component 310-a may include circuitry 330-a-2 and the component 310-b may include circuitry 330-b-1, or the component 310-a may include circuitry 330-a-1 and the component 310-b may include circuitry 330-b-2, and so on. For components 310 that are implemented in accordance with a back-side bonding, a conductive path 360 may pass through the respective substrate 320, such as using a through-silicon via (TSV) through the respective substrate 320.

Although the example of FIG. 3 illustrates a single component 310-b bonded with a single component 310-a, the described techniques may be implemented in accordance with multiple components 310-b being bonded with a single component 310-a (e.g., at different positions on the component 310-a in an x-direction, a y-direction, or both), or multiple components 310-a being bonded with a single component 310-b. For example, circuitry 330-a of a component 310-a (e.g., as memory controller circuitry) may be coupled with multiple instances of circuitry 330-b (e.g., as multiple instances of memory array circuitry) of multiple components 310-b, among other examples. In some examples, circuitry 330-a may include interposer circuitry (e.g., implementing the component 310-a as a silicon interposer), which may include circuitry formed from a doped portion of a substrate 320-a, or circuitry formed over a substrate 320-a (e.g., without transistor circuitry, with interconnection traces), or a combination thereof that provides a coupling between multiple instances of circuitry 330-b of multiple components 310-b bonded with different locations of the component 310-a.

The system 300 may implement one or more portions of diamond-form carbon 340 along the interface 350. In some examples, the diamond-form carbon 340 may be formed in a layer along the interface 350 (e.g., in an xy-plane), through which any quantity of one or more conductive paths 360 may extend. For example, a conductive path 360 may include a conductor portion 365-a (e.g., of the component 310-a, between the interface 350 and the substrate 320-a) and a conductor portion 365-b (e.g., of the component 310-b, between the interface 350 and the substrate 320-b), and the conductor portion 365-b may be fused with the conductor portion 365-a along the interface 350 (e.g., through the diamond-form carbon 340). In the example of FIG. 3, the diamond-form carbon 340 is illustrated as a portion of the component 310-a (e.g., as a surface layer of the component 310-a, as a bonding layer of the component 310-a, before bonding with the component 310-b). In some other examples, diamond-form carbon 340 may be a portion of the component 310-b, or respective portions of both the component 310-a and the component 310-b (e.g., supporting a diamond-to-diamond bonding).

In some examples, the system 300 may include one or more portions of diamond-form carbon 345 along the interface 350 (e.g., between the conductor portion 365-a and the conductor portion 365-b, along a fusion interface between conductor portions 365, along a conductive path 360). In some examples, a presence of diamond-form carbon 345 along a conductive path 360 may be indicative of a layer of diamond-form carbon 340 being fractured by conductor portions 365 during a fusion operation, which may be a result of a thermal expansion of a conductor portion 365-a into the diamond-form carbon 340 (e.g., along the positive z-direction), a thermal expansion of a conductor portion 365-b info the diamond-form carbon 340 (e.g., along the negative z-direction), or both, among other phenomena. In some other examples, portions of diamond-form carbon 345 may be omitted, such as when diamond-form carbon 340 is removed over or not formed over conductor portions 365, for example.

The presence of diamond-form carbon 340 along the interface 350 may support improved characteristics of the system 300. For example, diamond-form carbon may have a heat transfer coefficient of around 800-2200 W/(m*K) (e.g., depending on the size of sp3 carbon grains in the diamond-form carbon 340), which may be orders of magnitude higher than other materials (e.g., silicon-based dielectric materials, such as silicon oxide which may have a heat transfer coefficient around 0.1–0.2 W/(m*K)) used along a bonding interface. Accordingly, diamond-form carbon 340 may support relatively improved heat rejection (e.g., improved vertical heat transfer along the z-direction, improved lateral heat transfer in an xy-plane) by the system 300 (e.g., reduced thermal resistance along the z-direction, reduced hot spots at locations along an xy-plane). Such improvements may, in some examples, be leveraged to reduce or eliminate dummy contacts or other conductor material included in a component 310 for the sake of heat transfer (e.g., different than conductor material included for carrying electrical signals or power). Diamond-form carbon 340 may also have relatively strong electrical isolation (e.g., insulation, band gap) characteristics, such as having a dielectric constant of around 3–6 (e.g., depending on the size of sp3 carbon grains in the diamond-form carbon 340), which may be comparable to other dielectric materials implemented along an interface 350 (e.g., silicon-based dielectric materials, such as SiCN, which may have a dielectric constant around 4–4.5).

In some examples, diamond-form carbon 340 may be integrated with other features (e.g., thermally-enhancing features), such as a thermal distribution network (TDN), heat pipes, thermal siphons, silicon or copper slugs, or vapor coolers, among other features. For example, a system 300 may include one or more thermal vias that are electrically non-functional (e.g., do not support an interconnection between instances of circuitry 330, do not contribute to a conductive path 360) but further support enhanced thermal performance. In an illustrative example of such thermal vias, the component 310-a may include one or more other conductor portions 365 (not shown) that are not included in a conductive path 360 (e.g., electrically coupled with circuitry 330-a, electrically isolated from circuitry 330-a) but may be coupled with (e.g., in contact with) diamond-form carbon 340, the component 310-b may include one or more other conductor portions 365 (not shown) that are not included in a conductive path 360 (e.g., electrically coupled with circuitry 330-b, electrically isolated from circuitry 330-b) but may be coupled with (e.g., in contact with) diamond-form carbon 340, or a combination thereof. In some such examples, other conductor portions 365 (e.g., of thermal vias) of the component 310-a and of the component 310-b may be bonded (e.g., fused, across an interface 350, with or without corresponding portions of diamond-form carbon 345), which may support forming thermal vias that extend between the components 310-a and 310-b (e.g., across the interface 350) without an electrical coupling with circuitry 330-a, circuitry 330-b, or both.

Diamond-form carbon 340 may also have a relatively high density (e.g., around 3.5–3.6g/cm³, depending on the size of sp3 carbon grains in the diamond-form carbon 340), which may be suitable for also providing a barrier function (e.g., replacing one or more layers of a barrier material, such as a metal barrier or a moisture barrier). In some examples, the diamond-form carbon 340 may support improved bonding characteristics (e.g., relatively high bond strength) which may, in some examples, be implemented as a direct bond (e.g., including covalent bonding) between the diamond-form carbon 340 and a substrate 320 (e.g., substrate 320-b, in accordance with a back-side bonding of the component 310-b, as a direct bonding with crystalline silicon). Thus, in accordance with these and other examples, diamond-form carbon 340 may may have a relatively low electrical conductivity and a relatively high thermal conductivity, and may support relatively higher bonding strength and relatively lower conductor and moisture migration rates than other materials, which may provide relatively improved performance of a system 300 in a relatively smaller package size.

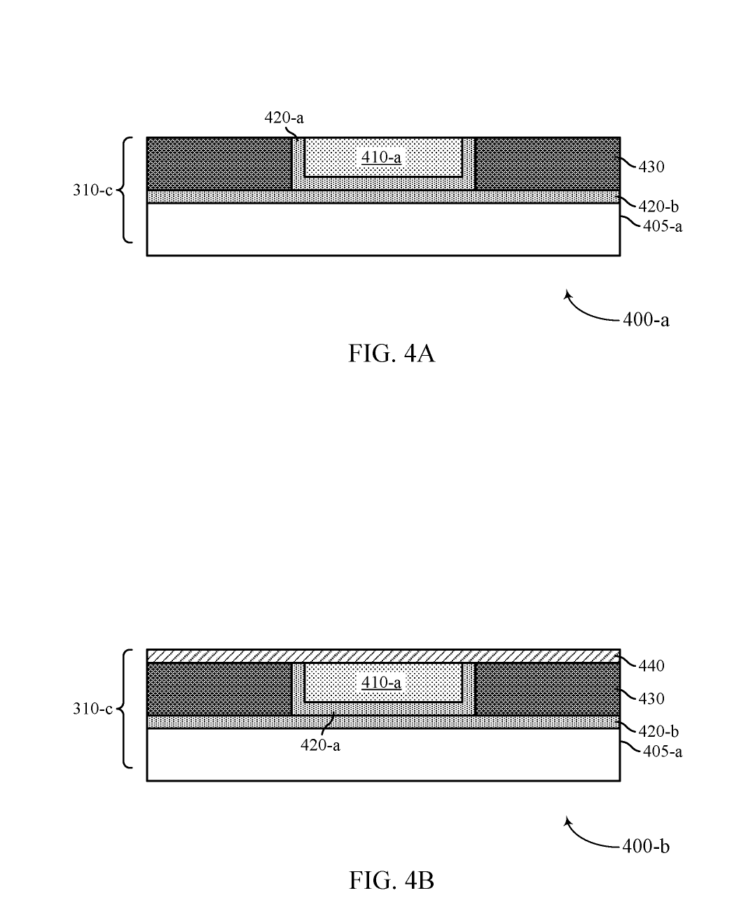

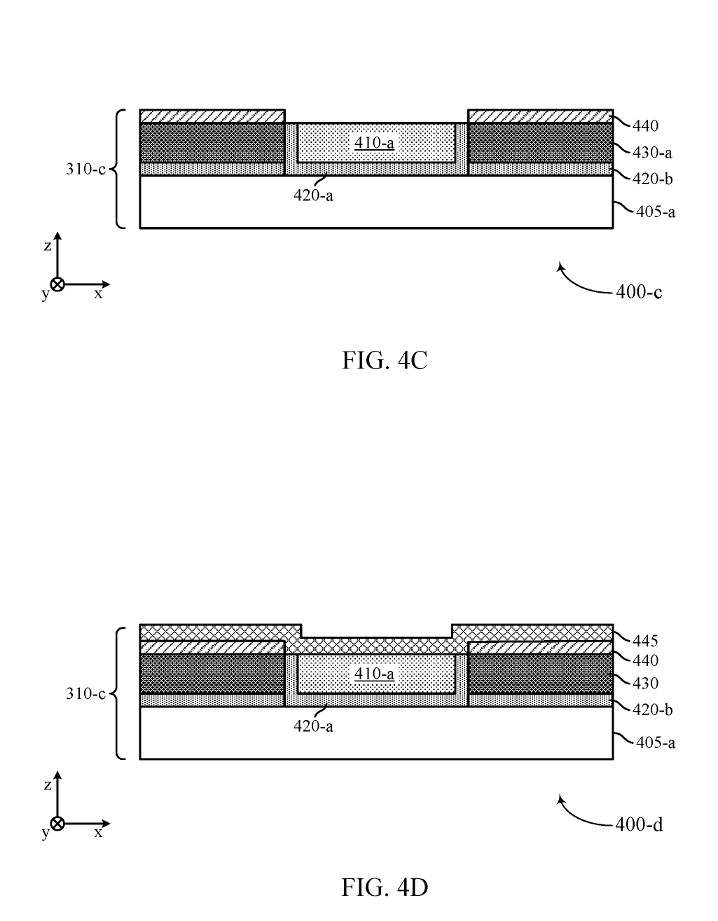

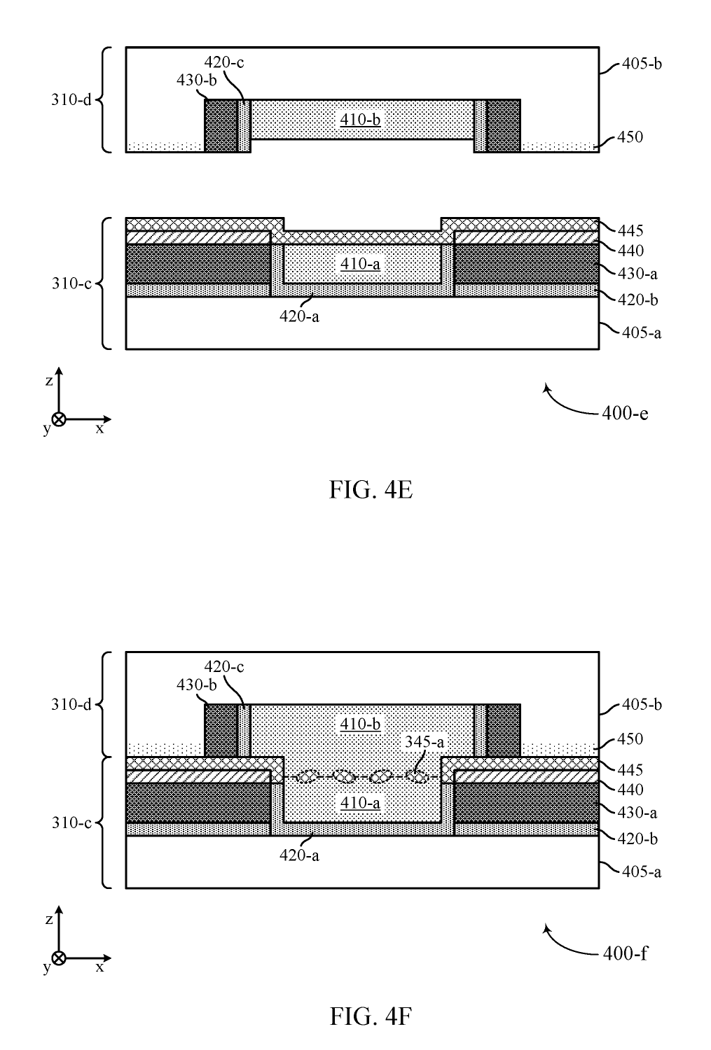

FIGS. 4A-4F show examples of fabrication operations that support diamond-based hybrid bonding for stacked semiconductor systems in accordance with examples as disclosed herein. For example, FIGS. 4A-4F may illustrate a sequence of operations for fabricating aspects of a system 400 (e.g., a stacked semiconductor system), which may be an example of a system 100, or a portion thereof (e.g., a host system 105, a memory system 110, or a combination thereof), a system 200, a system 300, or another implementation of a stacked semiconductor system (e.g., a memory component, a processing component).

Each of FIGS. 4A-4F may illustrate aspects of the system 400 after different subsets of the fabrication operations for forming the system 400 (e.g., illustrated as a system 400-a after a first set of one or more fabrication operations, as a system 400-b after a second set of one or more fabrication operations, and so on). Each view of FIGS. 4A-4F may be described with reference to an x-direction, a y-direction, and a z-direction of the illustrated coordinate system, which may correspond to the respective directions described with reference to the system 300. Aspects of the system 400 may be illustrated in accordance with a cut plane (e.g., along an xz-plane) to show embedded features of the system 400.

Operations illustrated in and described with reference to FIGS. 4A-4F may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the system 400. In some examples, operations performed by such a manufacturing system may be supported by a process controller or its components as described herein (e.g., including instructions stored in a non-transitory computer-readable medium that are executable by a processing system to cause the manufacturing system to perform the operations).

Although aspects of the system 400 illustrate examples of relative dimensions and quantities of various features (e.g., associated with a single conductive path 360), aspects of the system 400 may be implemented with other relative dimensions or quantities of such features in accordance with examples as disclosed herein. Moreover, aspects of the system 400 may be repeated in various manners (e.g., along the x-direction, along the y-direction, along the z-direction) to support two-dimensional arrays of conductive paths 360, among other repeated features. In the following description of the system 400, some methods, techniques, processes, and operations may be performed in different orders, or at different times, or otherwise modified. Further, some operations for fabricating a system 400 may be omitted from the described fabrication operations, or other operations may be added to the described fabrication operations.

FIG. 4A shows the system 400 (e.g., as a system 400-a) after a first set of one or more fabrication operations. For example, the first set of operations may include providing at least a portion of a component 310-c (e.g., as a semiconductor wafer, as a stack of semiconductor wafers, as a semiconductor die, as a stack of semiconductor dies). In some examples, the component 310-c may be provided on a carrier, such as a carrier wafer. Prior to or as a result of the first set of operations, the component 310-c may include at least a portion 405-a, which may include one or more substrates 320 and one or more instances of circuitry 330 (e.g., formed at least in part from doped portion(s) of the substrate(s) 320, formed without doped portions of the substrate(s) 320). In some examples, the provided component 310-c may include other portions described with reference to formation operations of the first set of operations, among other portions.

In some examples, the first set of operations may include forming a material 410-a (e.g., a conductor material, a metal material, such as copper) that may, in some examples (e.g., to support a conductive path 360), be electrically coupled with circuitry 330 of the portion 405-a (e.g., as a portion of a conductive path 360, corresponding to a conductor portion 365-a). In some other examples (e.g., to support a thermal via), the material 410-a may be isolated from circuitry 330 of the portion 405-a. In some examples, material 410-a may be formed in a back-end-of-line (BEOL) contact formation operation, which may be on a front side or back side relative to a substrate 320 (e.g., of the portion 405-a). In some examples, the material 410-a may be a back side of a TSV through a substrate 320 of the portion 405-a. The material 410-a may be electrically coupled with a metal contact or a BEOL conductor (e.g., an interconnection conductor, a conductive trace, a conductive line), among other examples.

In some examples, the first set of operations may include forming a material 420-a, a material 420-b, or both (e.g., before forming the material 420-a). Each of the materials 420 may be a barrier materials that, in some examples, prevent or suppress migration of the material 410-a (e.g., copper) or moisture to other portions (e.g., portion 405-a) of the component 310-c. The material 420-a may include tantalum, tantalum nitride, or titanium nitride, among other barrier materials. The material 420-b may include silicon carbon nitride (SiCN) or titanium nitride, among other barrier materials. In some examples, the first set of operations may include forming a material 430-a (e.g., a dielectric material, before or after forming the material 410-a). The material 430-a may include silicon dioxide, tetraethyl orthosilicate (TEOS), or other dielectric material. In some examples, the first set of operations may include a thinning operation (e.g., a chemical-mechanical planarization (CMP) operation) that reduces a thickness of at least the material 410-a and the material 430 (e.g., along the z-direction), and provides a planarized surface (e.g., in an xy-plane)

FIG. 4B shows the system 400 (e.g., as a system 400-b) after a second set of one or more fabrication operations. For example, the second set of operations may include forming a material 440 over a surface of the component 310-c. The material 440 may be a substrate material (e.g., a carbon substrate) that supports later formation of diamond-form carbon. In some examples, the material 440 may be a diamond-like carbon (DLC) material, which may include a combination of sp2 carbon (e.g., graphitic carbon) and sp3 carbon (e.g., diamond-form carbon), such as in an amorphous mixture. In some examples, the material 440 may include a lower proportion of sp2 carbon than sp3 carbon. For example, the material 440 may include 45% or less sp2 carbon and 55% or less sp3 carbon, or 30% or less sp2 carbon and 70% or more sp3 carbon, or 20% or less sp2 carbon and 80% or more sp3 carbon. The material 440 may be formed as a layer on the component 310-c, which may involve a low-temperature DLC sputtering operation. The material 440 may have relatively lower thermal conductivity than diamond-form carbon 340, relatively lower mechanical properties than diamond-form carbon 340, or both. However, the material 440 may have a relatively greater bonding strength with the material 430 than diamond-form carbon, and may improve formation (e.g., growth, nucleation) of later-formed diamond-form carbon (e.g., diamond-form carbon 340).

FIG. 4C shows the system 400 (e.g., as a system 400-c) after a third set of one or more fabrication operations. For example, the third set of operations may include removing portions of the material 440 over the material 410-a (e.g., exposing a top surface of the material 410-a, forming openings through the material 410-a over the material 410-a). In some examples, the third set of operations may also include removing portions of the material 440 over portions of the material 420-a (e.g., exposing a top surface of the material 420-a). Removing the material 440 may involve a photo patterning operation, a dry etch operation, a wet cleaning operation, or a combination thereof. After the third set of operations, the material 410-a may be below (e.g., recessed below, along the negative z-direction) a surface of the material 440.

FIG. 4D shows the system 400 (e.g., as a system 400-d) after a fourth set of one or more fabrication operations. For example, the fourth set of operations may include forming the material 445 (e.g., as a layer of material 445, as one or more portions of the material 445, as one or more patches of the material 445, over the material 440, over the material 410-a, over an exposed surface of the material 420-a, where applicable). The material 445 may be an example of diamond-form carbon 340, and may include nanocrystalline diamond (e.g., nanocrystalline sp3 carbon). The material 445 may be purely carbon, with more activation sites than transitional SiCN or SiOC-related dielectrics that may be used in other examples of hybrid bonding.

The material 445 may be capable of nucleation and growth on the material 440 (e.g., a carbon substrate, DLC) and the material 410-a (e.g., copper), which may be relatively uniform over the material 440 and the material 410-a. For example, the material 445 may be in-situ grown from the material 440 (e.g., grown from a carbon substrate, grown from a DLC substrate) and, in some examples, at least some of the material 440 (e.g., at a top surface) may be converted into the material 445. The material 445 may include grains of sp3 carbon that are larger than grains of sp3 carbon in the material 440, such including grains of sp3 in the material 445 that are 100 nm or larger. A change in size of grains of sp3 carbon may include a transition to larger grains of sp3 carbon along the positive z-direction that is associated with a boundary (e.g., in an xy-plane) between the material 440 and the material 445, or a gradual transition along the z-direction that is not associated with an explicit boundary between the material 440 and the material 445. The material 445 may be free from sp2 carbon, or may have a lower concentration of sp2 carbon than the material 440. For example, the material 445 may have a concentration of sp3 carbon that is 90% or more, 95% or more, or 99% or more, and spectroscopy analysis of the material 445 may indicate a predominant peak associated with sp3 carbon, and may lack a peak associated with sp2 carbon. In some examples, non-uniformities between regions over material 410-a and material 440, or other surface irregularities, may be resolved with a planarization operation after forming the material 445, which may include a CMP operation using a diamond nanoparticle slurry.

The material 445 may be formed in a relatively low-temperature operation (e.g., at or below 350° C., at or below 300° C., at or below 250° C.) compared to other diamond formation techniques, and the material 445 may be referred to as low-temperature growth diamond (LTGD). For example, the material 445 may be formed at a temperature that is similar to a temperature used to form at least some of the portion 405-a, or is compatible with features formed in the portion 405-a. For example, the material 445 may be formed at a temperature that is compatible with BEOL features of the component 310-c. Relatively higher temperatures during the formation of material 445 may be associated with relatively larger grains of sp3 carbon in the material 445, which may result in improved properties (e.g., higher thermal conductivity, higher density, greater electrical isolation, greater strength) compared with material 445 having relatively smaller grains of sp3 carbon. For example, diamond-form carbon in the material 445 that is formed as LTGD (e.g., at 350° C., which may be compatible with BEOL features of the component 310-c) may include grains of sp3 carbon in the range of 200-250 nm. In some examples, as part of the fourth set of operations or after the fourth set of operations, the component 310-c may undergo a post-annealing operation (e.g., at an elevated temperature), which may support growing relatively larger grains of sp3 carbon, which may further improving properties of the material 445.

In some examples, such temperatures may be implemented to form the material 445 at a rate of several nanometers per hour, such as five or more nanometers per hour, to reach a target thickness (e.g., along the z-direction), such as a thickness in the range of tens of nanometers or hundreds of nanometers (e.g., a target thickness within a range of 50–150 nm, a target thickness within a range of 80–120 nm, a target thickness of approximately 100 nm). Some examples of forming the material 445 may include diamond seeding, an addition of an impurity gas (e.g., methane, carbon dioxide, nitrogen oxide), or both to increase growth rate of the material 445.

FIG. 4E shows the system 400 (e.g., as a system 400-e) after a fifth set of one or more fabrication operations. For example, the fifth set of operations may include providing a component 310-d (e.g., as a semiconductor wafer, as a stack of semiconductor wafers, as a semiconductor die, as a stack of semiconductor dies). The component 310-c may include at least a portion 405-b, which may include one or more substrates 320 and one or more instances of circuitry 330 (e.g., formed at least in part from doped portion(s) of the substrate(s) 320, formed without doped portions of the substrate(s) 320). The component 310-c may also include a material 410-b (e.g., a conductor material, such as copper), which may be the same as the material 410-a or may be different than the material 410-a. In some examples (e.g., to support a conductive path 360), the material 410-b may be coupled with circuitry 330 of the component 310-d (e.g., of the portion 405-b). In some other examples (e.g., to support a thermal via), the material 410-b may be isolated from circuitry 330 of the component 310-d (e.g., of the portion 405-b). In some examples, the component 310-c may also include a material 420-c (e.g., a barrier material), a material 430-b (e.g., a dielectric material), or both. In some examples, the material 410-b may be formed on back side of the component 310-d, and may be a portion of or coupled with a TSV through a substrate 320 of the portion 405-b.

In some examples, the fourth set of operations may include a thinning operation (e.g., an etching operation, a CMP thinning operation) that reduces a thickness (e.g., along the z-direction) of the material 445. In some examples, such thinning may be implemented to support portions of the material 445 along a conductive path 360 being fractured during fusion of the material 410-a with the material 410-b (e.g., such that the material 445 is in-situ broken during subsequent operations). To support such techniques, the material 410-a may be recessed (e.g., along the negative z-direction) from a surface of the component 310-c, or the material 410-b may be recessed (e.g., along the positive z-direction) from a surface of the component 310-d, or both. In some other examples, portions of the material 445 may be removed over portion(s) of the material 410-a (e.g., in a patterning operation).

In some examples, the fourth set of operations may include a surface treatment of the component 310-c, the component 310-d, or both. For example, a material 450 may be formed at a surface of the component 310-d, or a similar material may be formed at a surface of the component 310-c (not shown), or both. Such surface treatments may prepare the component 310-c and 310-d to form bonds (e.g., covalent bonds) along an interface 350. In some examples, such techniques may include forming hydroxyl groups on surfaces of the material 445 (e.g., forming hydroxyl groups bonded with carbon atoms of the material 445), or forming hydroxyl groups on surfaces of the component 310-d (e.g., forming hydroxyl groups bonded with silicon atoms of the component 310-d, such as silicon atoms of a substrate 320 of the component 310-d when configured with a back-side bonding), or both. Additionally, or alternatively, such techniques may include forming hydrogen bonds on surfaces of the material 445 (e.g., bonding hydrogen atoms with carbon atoms of the material 445), or forming hydrogen bonds on surfaces of the component 310-d (e.g., bonding hydrogen atoms with silicon atoms of the component 310-d, such as silicon atoms of a substrate 320 of the component 310-d when configured with a back-side bonding), or both. For example, the component 310-c and the component 310-d may be enclosed in a chamber that is pumped down to a low vacuum, and hydrogen plasma may be added to the chamber that forms hydrogen on surfaces of the component 310-c and the component 310-d without oxidizing material 410-a or material 410-b.

FIG. 4F shows the system 400 (e.g., as a system 400-f) after a sixth set of one or more fabrication operations. For example, the sixth set of operations may include performing a hybrid bonding operation to bond the component 310-c with the component 310-d.

The hybrid bonding operation may include fusing one or more portions of the material 445 at a surface of the component 310-c with a surface of the component 310-d. In some examples, such bonding may include forming bonds (e.g., covalent bonds) between the material 445 (e.g., carbon atoms of the material 445) and a material at the surface of the component 310-d (e.g., silicon atoms of the component 310-d, such as silicon atoms of a substrate 320 of the component 310-d when configured with a back-side bonding). For example, an inert gas may be added to a chamber that holds the component 310-c and the component 310-d, and the component 310-c and the component 310-d may undergo ion bombardment that breaks off hydroxyl groups, hydrogen atoms, or both that may have been added during the fifth set of operations, which may support direct bonding (e.g., direct carbon-to-silicon bonding) between the component 310-c and the component 310-d. Such techniques may support significantly improved heat transfer between the component 310-c and the component 310-d compared to when other dielectric materials are used along an interface 350, and the relatively high density of the material 445 may also support a relatively strong barrier characteristic that impedes migration of conductor material (e.g., from materials 410).

The hybrid bonding operation may also include coupling circuitry 330 of the portion 405-a with circuitry 330 of the portion 405-b based on fusing the material 410-a with the material 410-b. In some examples, such fusion may be supported by an elevated temperature during the bonding, such as a temperature of or above 250° C., which also may support an annealing of the material 410-a, the material 410-b, or both, or continued growth of grains of sp3 carbon in the material 445, or a combination thereof. In some examples, fusing the material 410-a with the material 410-b may fragment the material 445 into portions of diamond-form carbon 345-a. For example, a coefficient of thermal expansion (CTE) of the materials 410 (e.g., copper) may be relatively high (e.g., 16–16.7 m/(m*degC)) compared to the CTE of material 445, which may be relatively low (e.g., 1.1–1.3x10⁻⁶ m/(m*degC)). Thus, the material 410-a and the material 410-b may expand toward each other at elevated temperatures, expanding into a recess zone between the respective material 410 and a surface of the respective component 310. Such expansion may fracture the material 445 into pieces, between which the materials 410-a and 410-b may fuse together, thereby forming an interconnection that supports a conductive path.

Thus, in accordance with these and other examples, a system (e.g., a semiconductor system, a system 100 or portion thereof, a system 200 or portion thereof, a system 300, a system 400) may be formed with a first substrate 320 (e.g., of a first component 310), first circuitry 330 (e.g., formed at least in part from a doped portion of the first substrate 320, formed without a doped portion of the first substrate 320), a second substrate 320 (e.g., of a second component 310), and second circuitry 330 (e.g., formed at least in part from a doped portion of the second substrate 320, formed without a doped portion of the second substrate 320). Such a system may also include one or more portions of diamond-form carbon 340 (e.g., of a material 445) along an interface 350 (e.g., a bonding interface) between the first substrate 320 and the second substrate 320, the second circuitry 330 being electrically coupled with the first circuitry 330 via one or more conductive paths 360 (e.g., including conductor portions 365, including materials 410) through the interface 350. The diamond-form carbon 340 may be formed in a layer along the interface 350, through which the conductive path(s) 360 extend, and conductive path(s) 360 may, in some examples, be surrounded by one or more portions of diamond-form carbon 340. The diamond-form carbon 340 may have a relatively low electrical conductivity and a relatively high thermal conductivity, and may support relatively higher bonding strength and relatively lower conductor and moisture migration rates than other techniques, which may provide relatively improved performance of such a system in a relatively smaller package size.

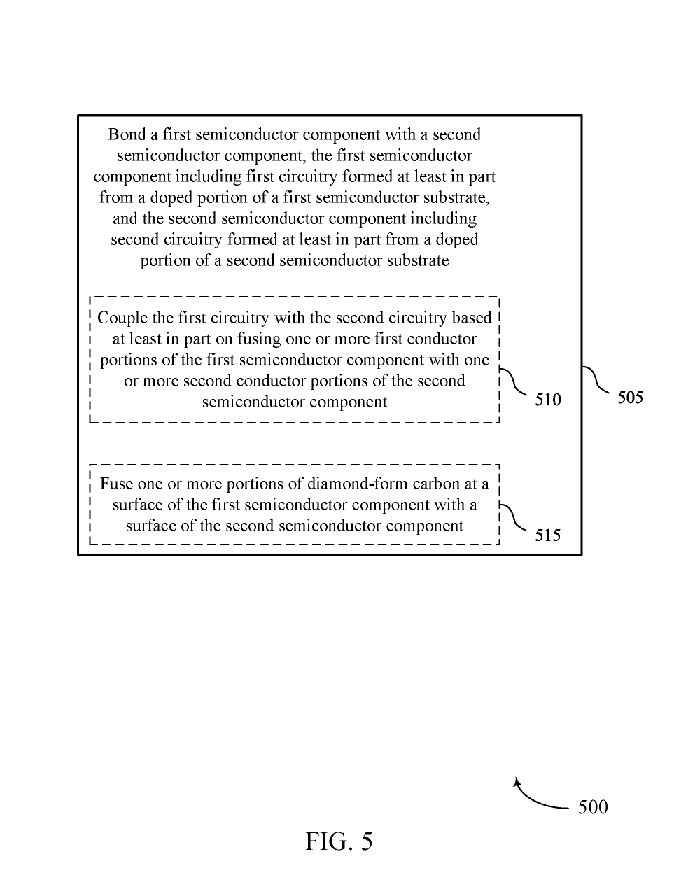

FIG. 5 shows a flowchart illustrating a method 500 that supports diamond-based hybrid bonding for stacked semiconductor systems in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include bonding a first semiconductor component with a second semiconductor component, the first semiconductor component including first circuitry formed at least in part from a doped portion of a first semiconductor substrate, and the second semiconductor component including second circuitry formed at least in part from a doped portion of a second semiconductor substrate.

In some examples, at 510, the bonding may include coupling the first circuitry with the second circuitry based at least in part on fusing one or more first conductor portions of the first semiconductor component with one or more second conductor portions of the second semiconductor component.

In some examples, at 515, the bonding may include fusing one or more portions of diamond-form carbon at a surface of the first semiconductor component with a surface of the second semiconductor component.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for bonding a first semiconductor component with a second semiconductor component, the first semiconductor component including first circuitry formed at least in part from a doped portion of a first semiconductor substrate, and the second semiconductor component including second circuitry formed at least in part from a doped portion of a second semiconductor substrate, where the bonding includes coupling the first circuitry with the second circuitry based at least in part on fusing one or more first conductor portions of the first semiconductor component with one or more second conductor portions of the second semiconductor component and fusing one or more portions of diamond-form carbon at a surface of the first semiconductor component with a surface of the second semiconductor component.

Aspect 2: The method, apparatus, or non-transitory computer-readable medium of aspect 1, further including operations, features, circuitry, logic, means, or instructions, or any combination thereof for forming the one or more portions of diamond-form carbon based at least in part on forming a layer of the diamond-form carbon along the surface of the first semiconductor component.

Aspect 3: The method, apparatus, or non-transitory computer-readable medium of aspect 2, further including operations, features, circuitry, logic, means, or instructions, or any combination thereof for forming a layer of diamond-like carbon over a dielectric material of the first semiconductor component and forming the layer of the diamond-form carbon over the layer of diamond-like carbon.

Aspect 4: The method, apparatus, or non-transitory computer-readable medium of any of aspects 2 through 3, further including operations, features, circuitry, logic, means, or instructions, or any combination thereof for forming openings through the layer of diamond-like carbon over the one or more first conductor portions before forming the layer of diamond-form carbon.

Aspect 5: The method, apparatus, or non-transitory computer-readable medium of any of aspects 1 through 4, where fusing the one or more first conductor portions with the one or more second conductor portions fragments a layer of the diamond-form carbon, between the one or more first conductor portions and the one or more second conductor portions, into one or more second portions of the diamond-form carbon.

Aspect 6: The method, apparatus, or non-transitory computer-readable medium of any of aspects 1 through 5, where the one or more first conductor portions are recessed from the surface of the first semiconductor component before the bonding, the one or more second conductor portions are recessed from the surface of the second semiconductor component before the bonding, or both.

Aspect 7: The method, apparatus, or non-transitory computer-readable medium of any of aspects 1 through 6, where the bonding is performed in accordance with a wafer-to-wafer bonding, the first semiconductor component including a first semiconductor wafer and the second semiconductor component including a second semiconductor wafer.

Aspect 8: The method, apparatus, or non-transitory computer-readable medium of any of aspects 1 through 7, where the bonding is performed in accordance with a chip-to-chip bonding, the first semiconductor component including a first singulated semiconductor chip and the second semiconductor component including a second singulated semiconductor chip.

Aspect 9: The method, apparatus, or non-transitory computer-readable medium of any of aspects 1 through 8, where the bonding is performed in accordance with a chip-to-wafer bonding, the first semiconductor component including a semiconductor wafer and the second semiconductor component including a singulated semiconductor chip.

Aspect 10: The method, apparatus, or non-transitory computer-readable medium of any of aspects 1 through 9, where the bonding is performed in accordance with a chip-to-wafer bonding, the first semiconductor component including a singulated semiconductor chip and the second semiconductor component including a semiconductor wafer.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 11: A semiconductor system, including: a first semiconductor substrate; first circuitry formed at least in part from a doped portion of the first semiconductor substrate; a second semiconductor substrate; second circuitry formed at least in part from a doped portion of the second semiconductor substrate; and one or more portions of diamond-form carbon along a bonding interface between the first semiconductor substrate and the second semiconductor substrate, the second circuitry being electrically coupled with the first circuitry via one or more conductive paths through the bonding interface.

Aspect 12: The semiconductor system of aspect 11, where at least one of the one or more conductive paths is surrounded by one of the one or more portions of diamond-form carbon.

Aspect 13: The semiconductor system of any of aspects 11 through 12, where the diamond-form carbon is formed in a layer along the bonding interface through which the one or more conductive paths extend.

Aspect 14: The semiconductor system of any of aspects 11 through 13, where at least one of the one or more conductive paths includes: a respective first conductor portion between the bonding interface and the first semiconductor substrate; and a respective second conductor portion between the bonding interface and the second semiconductor substrate, the respective second conductor portion fused with the respective first conductor portion along the bonding interface.

Aspect 15: The semiconductor system of aspect 14, further including: one or more second portions of diamond-form carbon along the bonding interface between one or more respective first conductor portions and one or more respective second conductor portions.

Aspect 16: The semiconductor system of any of aspects 11 through 15, further including: one or more portions of diamond-like carbon between the first semiconductor substrate and the diamond-form carbon and in contact with the diamond-form carbon.

Aspect 17: The semiconductor system of aspect 16, further including: a dielectric layer between the first semiconductor substrate and the diamond-like carbon and in contact with the diamond-like carbon.

Aspect 18: The semiconductor system of any of aspects 11 through 17, further including: one or more portions of hydroxylated silicon between the second semiconductor substrate and the diamond-form carbon and in contact with the diamond-form carbon.

Aspect 19: The semiconductor system of any of aspects 11 through 18, where: the first circuitry includes memory array circuitry; and the second circuitry includes memory controller circuitry configured for accessing the memory array circuitry.

Aspect 20: The semiconductor system of any of aspects 11 through 19, where: the first circuitry includes memory array circuitry; and the second circuitry includes processing circuitry configured for performing operations using data storage of the memory array circuitry.

Aspect 21: The semiconductor system of any of aspects 11 through 20, where: the first circuitry includes memory array circuitry associated with a first storage architecture; and the second circuitry includes memory array circuitry associated with a second storage architecture.

Aspect 22: The semiconductor system of any of aspects 11 through 21, where: the doped portion of the first semiconductor substrate faces away from the bonding interface; and the doped portion of the second semiconductor substrate faces toward the bonding interface.

Aspect 23: The semiconductor system of any of aspects 11 through 22, where: the doped portion of the first semiconductor substrate faces toward the bonding interface; and the doped portion of the second semiconductor substrate faces toward the bonding interface.

Aspect 24: The semiconductor system of any of aspects 11 through 23, where: the doped portion of the first semiconductor substrate faces away from the bonding interface; and the doped portion of the second semiconductor substrate faces away from the bonding interface.

An apparatus is described. The following provides an overview of aspects of the apparatus as described herein:

Aspect 25: A semiconductor system formed by a process including: bonding a first semiconductor component with a second semiconductor component, the first semiconductor component including first circuitry formed at least in part from a doped portion of a first semiconductor substrate, and the second semiconductor component including second circuitry formed at least in part from a doped portion of a second semiconductor substrate, where the bonding includes: coupling the first circuitry with the second circuitry based at least in part on fusing one or more first conductor portions of the first semiconductor component with one or more second conductor portions of the second semiconductor component; and fusing one or more portions of diamond-form carbon at a surface of the first semiconductor component with a surface of the second semiconductor component.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
a first semiconductor substrate;
first circuitry formed at least in part from a doped portion of the first semiconductor substrate;
a second semiconductor substrate;
second circuitry formed at least in part from a doped portion of the second semiconductor substrate; and
one or more portions of diamond-form carbon along a bonding interface between the first semiconductor substrate and the second semiconductor substrate, the second circuitry being electrically coupled with the first circuitry via one or more conductive paths through the bonding interface.

2. The semiconductor system of claim 1, wherein at least one of the one or more conductive paths is surrounded by one of the one or more portions of diamond-form carbon.

3. The semiconductor system of claim 1, wherein the diamond-form carbon is formed in a layer along the bonding interface through which the one or more conductive paths extend.

4. The semiconductor system of claim 1, wherein at least one of the one or more conductive paths comprises:
a respective first conductor portion between the bonding interface and the first semiconductor substrate; and
a respective second conductor portion between the bonding interface and the second semiconductor substrate, the respective second conductor portion fused with the respective first conductor portion along the bonding interface.

5. The semiconductor system of claim 4, further comprising:
one or more second portions of diamond-form carbon along the bonding interface between one or more respective first conductor portions and one or more respective second conductor portions.

6. The semiconductor system of claim 1, further comprising:
one or more portions of diamond-like carbon between the first semiconductor substrate and the diamond-form carbon and in contact with the diamond-form carbon.

7. The semiconductor system of claim 6, further comprising:
a dielectric layer between the first semiconductor substrate and the diamond-like carbon and in contact with the diamond-like carbon.

8. The semiconductor system of claim 1, further comprising:
one or more portions of hydroxylated silicon between the second semiconductor substrate and the diamond-form carbon and in contact with the diamond-form carbon.

9. The semiconductor system of claim 1, wherein:
the first circuitry comprises memory array circuitry; and
the second circuitry comprises memory controller circuitry configured for accessing the memory array circuitry.

10. The semiconductor system of claim 1, wherein:
the first circuitry comprises memory array circuitry; and
the second circuitry comprises processing circuitry configured for performing operations using data storage of the memory array circuitry.

11. The semiconductor system of claim 1, wherein:
the first circuitry comprises memory array circuitry associated with a first storage architecture; and
the second circuitry comprises memory array circuitry associated with a second storage architecture.

12. The semiconductor system of claim 1, wherein:
the doped portion of the first semiconductor substrate faces away from the bonding interface; and
the doped portion of the second semiconductor substrate faces toward the bonding interface.

13. The semiconductor system of claim 1, wherein:
the doped portion of the first semiconductor substrate faces toward the bonding interface; and
the doped portion of the second semiconductor substrate faces toward the bonding interface.

14. The semiconductor system of claim 1, wherein:
the doped portion of the first semiconductor substrate faces away from the bonding interface; and
the doped portion of the second semiconductor substrate faces away from the bonding interface.

15. A method of forming a semiconductor system, comprising:
bonding a first semiconductor component with a second semiconductor component, the first semiconductor component comprising first circuitry formed at least in part from a doped portion of a first semiconductor substrate, and the second semiconductor component comprising second circuitry formed at least in part from a doped portion of a second semiconductor substrate, wherein the bonding comprises:
coupling the first circuitry with the second circuitry based at least in part on fusing one or more first conductor portions of the first semiconductor component with one or more second conductor portions of the second semiconductor component; and
fusing one or more portions of diamond-form carbon at a surface of the first semiconductor component with a surface of the second semiconductor component.

16. The method of claim 15, further comprising:
forming the one or more portions of diamond-form carbon based at least in part on forming a layer of the diamond-form carbon along the surface of the first semiconductor component.

17. The method of claim 16, further comprising:
forming a layer of diamond-like carbon over a dielectric material of the first semiconductor component; and
forming the layer of the diamond-form carbon over the layer of diamond-like carbon.

18. The method of claim 16, further comprising:
forming openings through the layer of diamond-like carbon over the one or more first conductor portions before forming the layer of diamond-form carbon.

19. The method of claim 15, wherein fusing the one or more first conductor portions with the one or more second conductor portions fragments a layer of the diamond-form carbon, between the one or more first conductor portions and the one or more second conductor portions, into one or more second portions of the diamond-form carbon.

20. The method of claim 15, wherein the one or more first conductor portions are recessed from the surface of the first semiconductor component before the bonding, the one or more second conductor portions are recessed from the surface of the second semiconductor component before the bonding, or both.

21. The method of claim 15, wherein the bonding is performed in accordance with a wafer-to-wafer bonding, the first semiconductor component comprising a first semiconductor wafer and the second semiconductor component comprising a second semiconductor wafer.

22. The method of claim 15, wherein the bonding is performed in accordance with a chip-to-chip bonding, the first semiconductor component comprising a first singulated semiconductor chip and the second semiconductor component comprising a second singulated semiconductor chip.

23. The method of claim 15, wherein the bonding is performed in accordance with a chip-to-wafer bonding, the first semiconductor component comprising a semiconductor wafer and the second semiconductor component comprising a singulated semiconductor chip.

24. The method of claim 15, wherein the bonding is performed in accordance with a chip-to-wafer bonding, the first semiconductor component comprising a singulated semiconductor chip and the second semiconductor component comprising a semiconductor wafer.

25. A semiconductor system formed by a process comprising:
bonding a first semiconductor component with a second semiconductor component, the first semiconductor component comprising first circuitry formed at least in part from a doped portion of a first semiconductor substrate, and the second semiconductor component comprising second circuitry formed at least in part from a doped portion of a second semiconductor substrate, wherein the bonding comprises:
coupling the first circuitry with the second circuitry based at least in part on fusing one or more first conductor portions of the first semiconductor component with one or more second conductor portions of the second semiconductor component; and
fusing one or more portions of diamond-form carbon at a surface of the first semiconductor component with a surface of the second semiconductor component.
